(19) United States
(12) Patent Application Publication
(10) Pub. No.: US 2009/0027131 A1
(43) Pub. Date: Jan. 29, 2009

(54) RING OSCILLATORS FOR CMOS TRANSISTOR BETA RATIO MONITORING

(76) Inventor: Shingo Suzuki, San Jose, CA (US)

Correspondence Address: K & L GATES LLP, 630 HANSEN WAY, PALO ALTO, CA, 94304, US

(21) Appl. No.: 12/176,908

(22) Filed: Jul. 21, 2008

Related U.S. Application Data
(60) Provisional application No. 60/961,750, filed on Jul. 25, 2007.

(51) Int. Cl. H03K 3/03

(52) U.S. Cl. 331/57

(57) ABSTRACT

This invention discloses a CMOS ring oscillator which comprises an odd number of inverting modules serially connected with each other with an output of a last stage inverting module coupled to an input of a first stage inverting module, each of the plurality of inverting modules always outputting a logic low voltage whenever being inputted a logic high voltage, all the forward signal paths of each of the plurality of inverting modules being formed by metal-oxide-silicon (MOS) transistors wherein all the gates of the MOS transistors being directly connected to the input of the respective inverting module, and at least one of the plurality of inverting modules having a negative feedback circuit.

### CROSS REFERENCE

This application claims the benefits of U.S. Provisional Patent Application Ser. No. 60/961,750, which was filed on Jul. 25, 2007 and entitled “Ring oscillators for beta ratio monitor.”

### BACKGROUND

The present invention relates generally to integrated circuit (IC) design, and, more particularly, to designing of ring oscillators for monitoring CMOS transistor beta ratio.

One of the issues in semiconductor manufacturing is how to monitor process variations from one processing lot to another and on locations across a single wafer. Beta ratio, which is defined as a ratio between the strength of the PMOS device and the strength of the NMOS device in a CMOS inverter, is one of the parameters developed to monitor such process variations. The beta ratio can significantly affect chip performance, yield, and power consumption. Ring oscillators, typically comprising of a chain of odd number of inverting modules, are most commonly used for monitoring the process variations. The inverting modules can be inverter, NAND gates or NOR gates, etc. FIG. 1 is a schematic diagram illustrating a conventional ring oscillator 100 which is comprised of an inverting module chain 102[0:N], where N is an odd integer number. An output, OUT, of the last stage inverting module 102[N] is feed back to an input of the first stage inverting module 102[0]. Specifically, the first stage inverting module 102[0] is implemented with a CMOS NAND gate 105[0], and the rest of the inverting modules [1:N] are implemented by CMOS inverters 105[1:N]. The NAND gate 105[0] has another input signal ENABLE. Apparently, the output signal OUT is logic NOT of the input signal ENABLE with a finite amount of time delay caused by the inverter chain 105[1:N]. When the input signal ENABLE is asserted, the feedback of the delayed output signal OUT causes the ring oscillator 100 to oscillate with an oscillation frequency determined by a total delay of the inverters 105[1:N]. The oscillation frequency is measured and used as an indication of a characteristic of the process that produces the ring oscillator 100. However, the oscillation frequency is typically not sensitive to the CMOS transistor beta ratio, as each typically sized inverter's delay is not very sensitive to the beta ratio. In order to device a ring oscillator that is more sensitive to the beta ratio, pseudo-NMOS and/or pseudo-PMOS ring oscillators are sometimes used. But these circuits tend to have a minimum operational condition problem, i.e., they cannot operate when power supply goes down to a certain voltage and/or when temperature is below a certain degree.

As such, what is desired is a ring oscillator that can better reflect the CMOS transistor beta ratio, yet having a wide operating range.

### SUMMARY

This invention discloses a CMOS ring oscillator which comprises an odd number of inverting modules serially connected with each other with an output of a last stage inverting module coupled to an input of a first stage inverting module, wherein at least one of the inverting modules comprises a negative feedback circuit.

According to one aspect of the present invention, the negative feedback circuit comprises a PMOS transistor with a source, drain and gate coupled to a high voltage power supply (VCC), an input of the at least one of the inverting modules and an output of the same modules, respectively.

According to another aspect of the present invention, the negative feedback circuit comprises a NMOS transistor with a source, drain and gate coupled to a ground (VSS), an input of the at least one of the inverting modules and an output of the same module, respectively.

The construction and method of operation of the invention, however, together with additional objectives and advantages thereof will be best understood from the following description of specific embodiments when read in connection with the accompanying drawings.

### BRIEF DESCRIPTION OF THE DRAWINGS

The drawings accompanying and forming part of this specification are included to depict certain aspects of the invention. A clearer conception of the invention, and of the components and operation of systems provided with the invention, will become more readily apparent by referring to the exemplary, and therefore non-limiting, embodiments illustrated in the drawings, wherein like reference numbers (if they occur in more than one view) designate the same elements. The invention may be better understood by reference to one or more of these drawings in combination with the description presented herein. It should be noted that the features illustrated in the drawings are not necessarily drawn to scale.

FIG. 1 is a schematic diagram illustrating a conventional ring oscillator.

FIG. 2 is schematic diagram illustrating an inverting module according to a first embodiment of the present invention.

FIG. 3 is a schematic diagram illustrating the inverting module of FIG. 2 being used in a ring oscillator.

FIG. 4 is schematic diagram illustrating another inverting module according to a second embodiment of the present invention.

FIG. 5 is a schematic diagram illustrating the inverting module of FIG. 4 being used in a ring oscillator.

FIG. 6 is a schematic diagram illustrating an alternative ring oscillator using the inverting modules of both FIG. 2 and 4.

FIG. 7 is a schematic diagram illustrating an alternative implementation of the inverting module in accordance with the present invention.

FIG. 8 is a schematic diagram illustrating an alternative implementation of the controllable inverting module 102[0] of FIG. 1.

FIG. 9 shows yet another alternative implementation 900 of the controllable inverting module 102[0] of FIG. 1.

FIG. 10 is a block diagram illustrating an exemplary beta ratio measurement system that employs the ring oscillators of the present invention.

FIG. 11 is plot diagram illustrating an exemplary method for converting frequency data into N/P beta ratio.

FIG. 12 is a flow chart diagram illustrating steps of the method of FIG. 11.

### DESCRIPTION

The present invention discloses a CMOS ring oscillator that can be used to measure CMOS transistor beta ratio. As the ring oscillator is comprised of CMOS transistors, it can operate at very low voltage and wide temperature range.

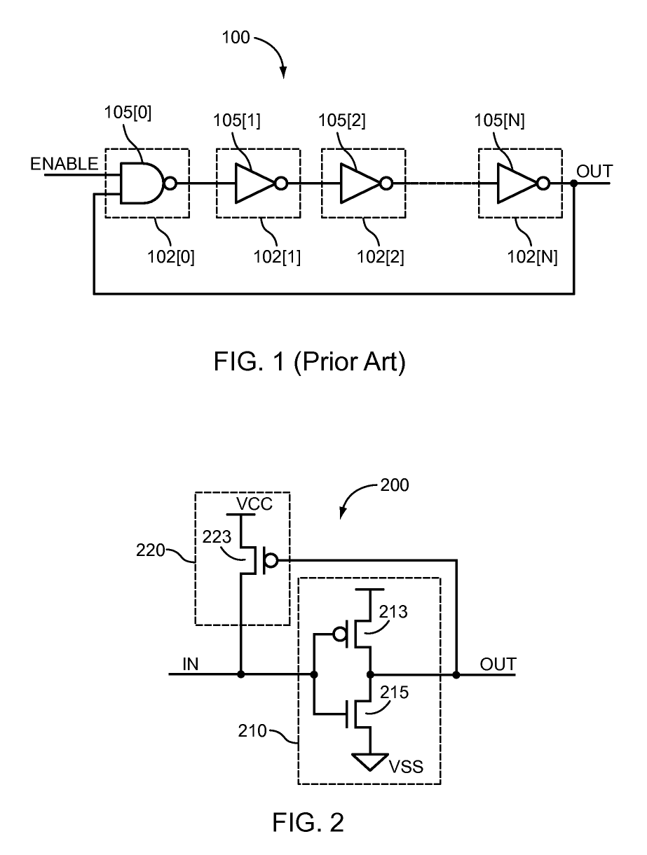

As depicted in FIG. 1, the oscillation frequency of the ring oscillator 100 is determined by the delay of the inverter chain 105[1:N], and the delay of the conventionally sized inverters 105[1:N] does not reflect the CMOS transistor beta ratio well. The present invention discloses novel inverting modules with delays can be drastically affected by the beta ratios for constructing ring oscillators.

FIG. 2 is schematic diagram illustrating an inverting module 200 according to a first embodiment of the present invention. The inverting module 200 comprises an inverter 210 and a feedback circuit 220. The inverter 210 is formed by a PMOS transistor 213 and a NMOS transistor 215 with gates connected together to an input node IN and drains connected together to an output node OUT. The feedback circuit 220 is implemented by a PMOS transistor 223 with a gate coupled to the node OUT, a drain coupled to the node IN, and a source coupled to a high voltage power supply VCC. Herein the term “coupled” means directly connected or connected through another component, but where that added another component supports the circuit function.

In operations, when the input node IN rises from 0 to 1, the output node OUT falls from 1 to 0 with no fighting condition posed by the feedback PMOS transistor 223, because the PMOS transistor 223 is off at the onset of the transition. When the input node IN falls from 1 to 0, the output node OUT rises from 0 to 1. The node IN's fall from 1 to 0 is resisted by the feedback PMOS transistor 223 as the PMOS transistor 223 is on at the onset of the transition. Apparently the strength of the PMOS transistor 223 must be lower than the pull-down strength at the node IN, which comes typically from a NMOS transistor in a previous stage inverting module of a ring oscillator.

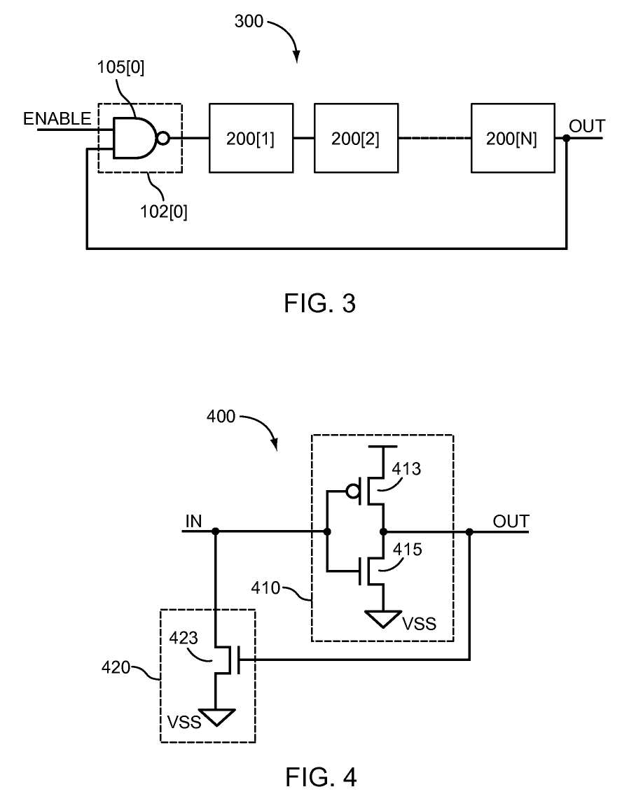

FIG. 3 is a schematic diagram illustrating the inverting module 200 of FIG. 2 being used in a ring oscillator 300. The inverting modules 200[1:N] replace the inverters 105[1:N] of FIG. 1, respectively. The ring oscillator 300 functions the same as the ring oscillator 100. But the oscillation frequency of the ring oscillator 300 is much more sensitive to the beta ratio than that of the ring oscillator 100. Compared to a balanced process where NMOS transistors and PMOS transistors have substantially equal strength, the ring oscillator 300 runs relatively faster when a skewed process produces a stronger NMOS transistors and weaker PMOS transistors. The ring oscillator 300 runs relatively slower when the NMOS transistors are weaker and the PMOS are stronger than in the balanced process.

FIG. 4 is schematic diagram illustrating another inverting module 400 according to a second embodiment of the present invention. Similar to the inverting module 200 of FIG. 2, the inverting module 400 comprises an inverter 410 and a feedback circuit 420. The inverter 410 is formed by a PMOS transistor 413 and a NMOS transistor 415 with gates connected together to an input node IN and drains connected together to an output node OUT. But the feedback circuit 420 is implemented by a NMOS transistor 423 with a gate coupled to the node OUT, a drain coupled to the node IN, and a source coupled to a ground VSS.

Referring again to FIG. 4, in operations, when the input node IN falls from 1 to 0, the output node OUT rises from 0 to 1 with no fighting condition posed by the feedback NMOS transistor 423, because the NMOS transistor 423 is off at the onset of the transition. When the input node IN rises from 0 to 1, the output node OUT falls from 1 to 0. The node IN's rise from 0 to 1 is resisted by the feedback NMOS transistor 423 as the NMOS transistor 423 is on at the onset of the transition. Apparently the strength of the NMOS transistor 423 must be lower than the pull-up strength at the node IN, which comes typically from a PMOS transistor in a previous stage inverting module of a ring oscillator.

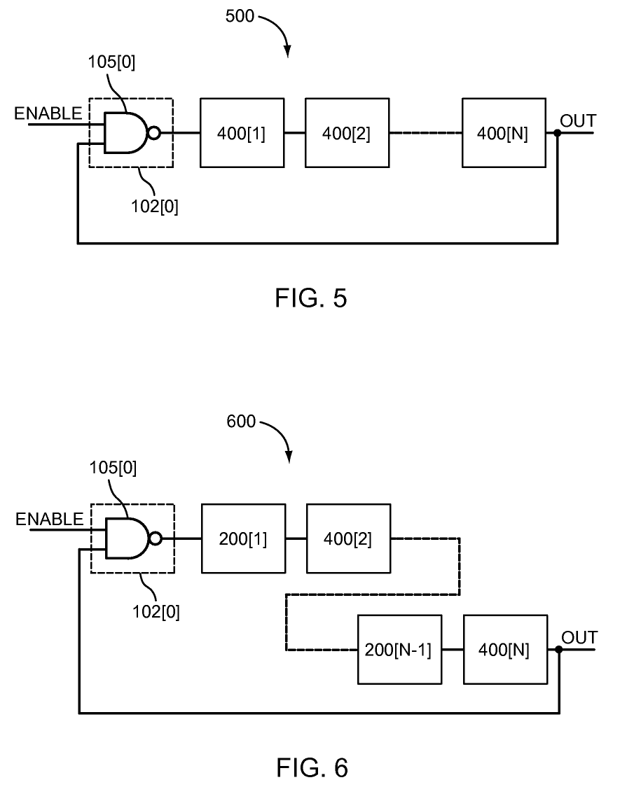

FIG. 5 is a schematic diagram illustrating the inverting module 400 of FIG. 4 being used in a ring oscillator 500. The inverting modules 400[1:N] replace the inverters 105[1:N] of FIG. 1, respectively. The ring oscillator 500 functions the same as the ring oscillator 100. But the oscillation frequency of the ring oscillator 500 is much more sensitive to the beta ratio than that of the ring oscillator 100. Compared to a balanced process where NMOS transistors and PMOS transistors have substantially equal strength, the ring oscillator 500 runs relatively slower when a skewed process produces a stronger NMOS transistors and weaker PMOS transistors. The ring oscillator 300 runs relatively faster when the NMOS transistors are weaker and the PMOS are stronger than in the balanced process.

FIG. 6 is a schematic diagram illustrating an alternative ring oscillator 600 using both the inverting module 200 of FIG. 2 and the inverting module 400 of FIG. 4. For illustration purpose, the inverting module 200 and the inverting module 400 are arranged alternately in replacing the inverting module 100 of FIG. 1. However, a skilled in the art would realize that the inverting module 200 or the inverting module 400 can be arranged in any order and in any number as long as the total number is an even one. Besides, referring back to FIGS. 2 and 4, although inverters 210 and 410 are used to form the inverting module 200 and 400, respectively, a skilled artisan would appreciate that many other inverting devices, such as a NAND gate and a NOR gate, can be used in place of the inverter 210 and 410. Apparently the feedback circuit 220 and 420 is not limited to the NMOS transistor 223 and 423, respectively. In essence, the feedback circuits 220 and 420 are simple negative feedback circuits which can be implemented by many other inverting devices, such as a simple inverter.

An advantage of the ring oscillators 300, 500 and 600 of the present invention is that the gates are all formed by pure CMOS circuit, so that the oscillating signals swing between the power rails VCC and VSS. Therefore, the ring oscillators 300, 500 and 600 can function properly at relatively wider power supply voltage range and temperature range than the pseudo-NMOS or pseudo-PMOS ring oscillator does.

In order to monitor the beta ratio of a process, all three kinds of ring oscillators 300, 500 and 600 of FIGS. 2, 4 and 6, respectively, are typically placed in the wafers and their oscillation frequencies measured after the process. Following TABLE 1 summarizes relative oscillation frequency results under different processing conditions.

TABLE 1

| | Oscillation frequency | | |
|---|---|---|---|
| Process conditions | Ring oscillator | Ring oscillator | Ring oscillator |
| (NP) | 300 (FREQ1) | 500 (FREQ2) | 600 (FREQ3) |
| TT | Medium | Medium | Medium |
| FS | Fast | Slow | Medium |
| SF | Slow | Fast | Medium |
| FF | Fast | Fast | Fast |
| SS | Slow | Slow | Slow |

In TABLE 1, under the “process condition” column, “TT” indicates that both the NMOS and PMOS transistors are typical; “FS” indicates that the NMOS transistor is faster (stronger) than typical, and the PMOS transistor is slower (weaker) than typical; “SF” indicates that the NMOS transistor is slower (weaker) than typical, and the PMOS transistor is faster (stronger) than typical; “FF” indicates that both the NMOS and PMOS transistors are faster (stronger) than typical; and “SS” indicates that both the NMOS and PMOS transistors are slower (weaker) than typical. Under the oscillation frequency columns, the “medium” frequency is in fact a reference frequency, with which the “fast” frequency and “slow” frequency are compared. For instance, the oscillation frequency (FREQ1) of the ring oscillator 300 under the “SF” process condition is “slow” which means FREQ1 is slower than when the ring oscillator 300 is in the “TT” process condition.

The N/P beta ratio can be monitored by monitoring the ratios of the three frequencies FREQ1, FREQ2 and FREQ3. When the beta ratio of a particular process condition is higher than that in the typical process condition, the three frequencies have the following relative relationship:

FREQ1>FREQ3>FREQ2 Eq. 1

When the beta ratio of a particular process condition is lower than that in the typical process condition, the three frequencies have the following relative relationship:

FREQ1<FREQ3<FREQ2 Eq. 2

When the beta ratio of a particular process condition is equal to that in the typical process condition, the three frequencies have the following relative relationship:

FREQ1=FREQ3=FREQ2 Eq. 3

For certain applications, precise design of the three ring oscillators 300, 500, and 600 to arrive at Eq. 1, Eq. 2, and Eq. 3 are not required to monitor the N/P beta ratio. In one embodiment of the present invention, only the ring oscillator 300 and the ring oscillator 500 are used. Furthermore, in another embodiment of the present invention, the two output frequencies (FREQ1 and FREQ2) are not necessarily equal to determine if the N/P beta ratio is centered.

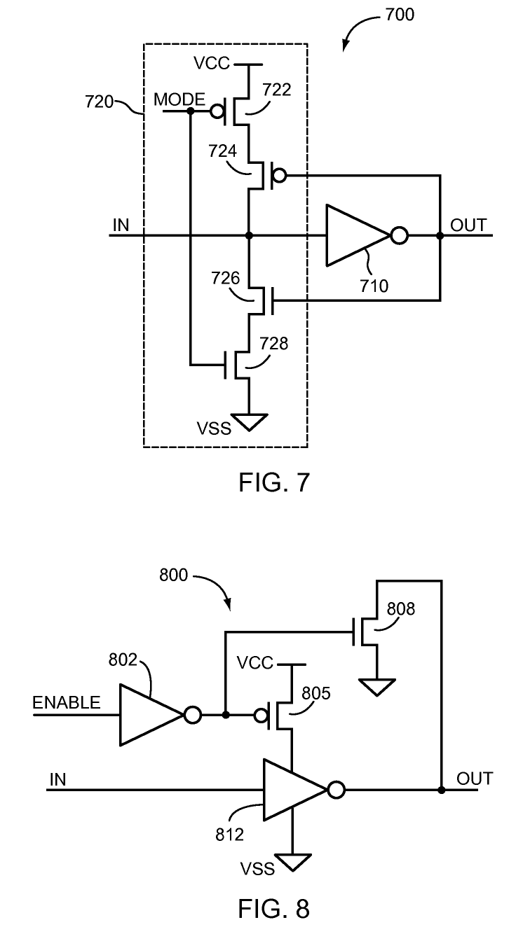

FIG. 7 is a schematic diagram illustrating an alternative implementation of the inverting module in accordance with the present invention. The inverting module 700 comprises an inverter 710 and a negative feedback circuit 720. The negative feedback circuit 720 comprises serially connected PMOS transistors 722 and 724 between an input node IN and the VCC, and serially connected NMOS transistors 726 and 728 between the input node IN and the VSS. Gates of the PMOS transistor 724 and the NMOS transistor 726 are coupled to an output node OUT. Gates of the PMOS transistor 722 and the NMOS transistor 728 are coupled to a signal MODE. When the signal MODE is in logic high, the PMOS transistor 722 is off and the NMOS transistor 728 is on, then the NMOS transistor 726 is engaged. As a result, the inverting module 700 is equivalent to the inverting module 400 of FIG. 4. On the other hand, when the signal MODE is in a logic low, the PMOS transistor 722 is on and the NMOS transistor 728 is off, then the PMOS transistor 724 is engaged. As a result, the inverting module 700 is equivalent to the inverting module 200 of FIG. 2. When the inverting module 700 is used in place of the inverters 105[1:N] of FIG. 1 (not shown), by applying a different voltage at the signal MODE, the same ring oscillator can be switched from an equivalence of the ring oscillator 300 of FIG. 3 to an equivalence of the ring oscillator 500 of FIG. 5.

FIG. 8 is a schematic diagram illustrating an alternative implementation 800 of the controllable inverting module 102[0] of FIG. 1. The inverting circuit 800 comprises inverters 802 and 812, a PMOS transistor 805 and a NMOS transistor 808. The signal ENABLE is coupled to an input of the inverter 802. When the signal ENABLE is in the logic high, the PMOS transistor 805 is turned on which conducts the VCC to the inverter 812. At this time, the inverting circuit 800 is enabled. When the signal ENABLE is in the logic low, the PMOS transistor 805 is turned off which cuts of the VCC to the inverter 812, while the NMOS transistor 808 is turned on which locks the node OUT to the VSS. At this time, the inverting circuit 800 is disabled. Apparently the inverting circuit 800 is functionally equivalent to the NAND gate 105[0] of FIG. 1.

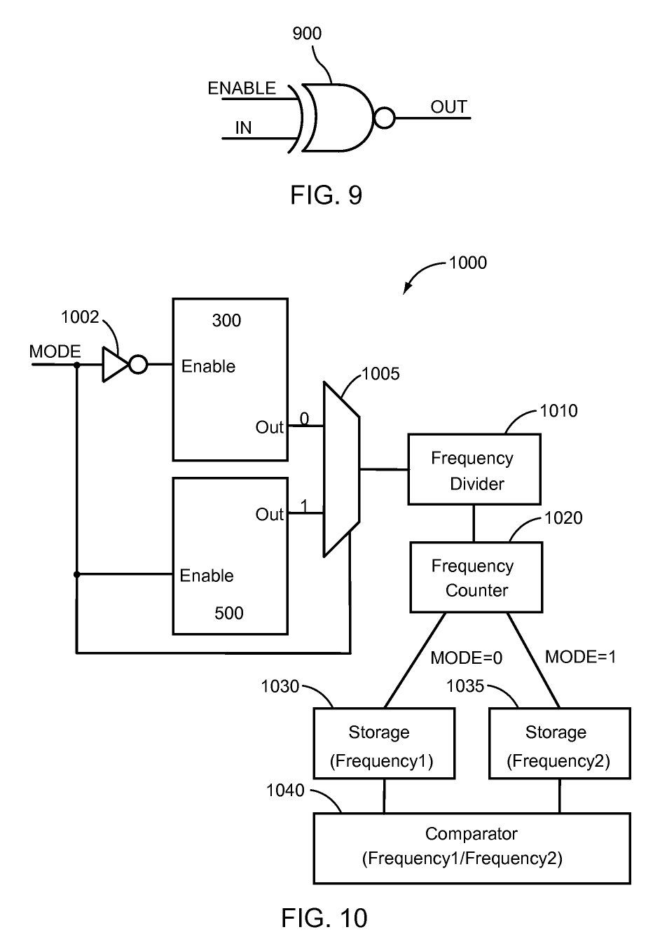

FIG. 9 shows yet another alternative implementation 900 of the controllable inverting module 102[0] of FIG. 1. The circuit 900 is simply a XOR gate. When used in the ring oscillator 100 of FIG. 1 in place of the NAND gate 105[0], the XOR gate functions as a controller at the control of the signal ENABLE to enable or disable the oscillation in the ring oscillator 100.

A skilled in the art would have no difficulty to use either the inverting circuit 800 or the XOR gate 900 in any of the ring oscillators 300, 500 and 600 in accordance with the present invention.

FIG. 10 is a block diagram illustrating an exemplary beta ratio measurement system 1000 that employs the ring oscillators of the present invention. An input signal MODE is connected to an inverter 1002, an Enable input of a block 500, and a selector of a multiplexor 1005. An output of the inverter 1002 is connected to an Enable input of a block 300. In one embodiment, the block 300 is the ring oscillator 300 of FIG. 3. The block 500 is the ring oscillators 500 of FIG. 5. An output of the block 300 is connected to an input of the multiplexor 1005, and an output of the block 500 is connected to another input of the multiplexor 1005. An output of the multiplexor 1005 is connected to an input of a Frequency Divider 1010. An output of the frequency divider 1010 is connected to an input of a frequency counter 1020. The frequency divider 1010 divides frequency of the input signal to a desired range for the frequency counter 1020 to have a better measurement of the frequency. The frequency counter 1020 generates a number that is a certain function of the input frequency. In one case, the generated number is equal to the input frequency. When the input signal MODE is at the logic low, the block 300 is enabled and a number (Frequency1) generated by Frequency Counter 1020 is stored in a storage block 1030. When the input signal MODE is at the logic high, the block 500 is enabled and a number (Frequency2) generated by the frequency counter 1020 is stored in another storage block 1035. A comparator 1040 compares the number (Frequency1) in the storage block 1030 with the number (Frequeny2) in the storage block 1035 to generate an N/P beta ratio.

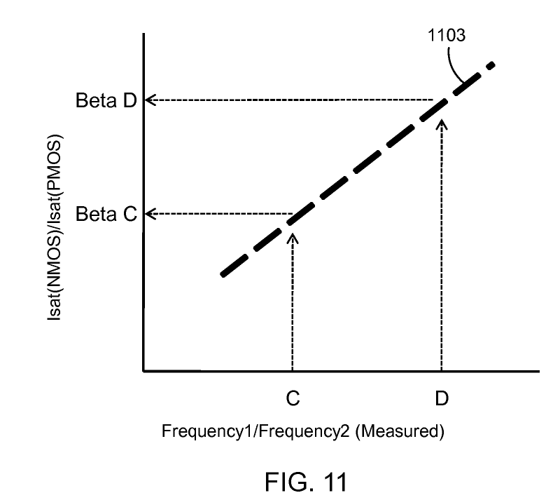

FIG. 11 is plot diagram illustrating an exemplary method for converting frequency data into N/P beta ratio. A Y-axis represents the N/P beta ratio. An X-axis represents a Frequency1/Frequency2 ratio which is obtained by the comparator 1040 of FIG. 10. An X-coordinate C indicates a measured data point of Frequency1/Frequency2. Another X-coordinate D is another measured data point of Frequency1/Frequency2. A line 1103 represents simulated data that correlates a measured data of Frequency1/Frequency2 to the associated N/P beta ratio. In one embodiment, N/P beta ratio is the ratio of NMOS saturated current (Isat) and PMOS saturated current (Isat). Coordinates C and D are extracted by the simulated line 1103 to obtained beta ratios, Beta C and Beta D, respectively.

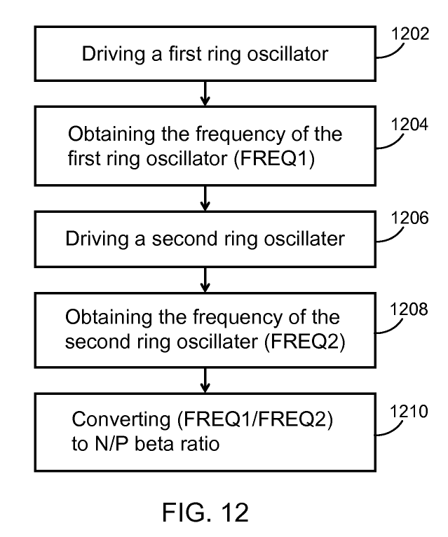

FIG. 12 is a flow chart diagram illustrating steps of the method of FIG. 11 which starts with a step 1202 where a first ring oscillator, such as the ring oscillator 300 of FIG. 300, is driven. In step 1204, a frequency of the first ring oscillator (FREQ1) is measured and obtained. In step 1206, a second ring oscillator, such as the ring oscillator 500 of FIG. 5, is driven. In step 1208, a frequency of the second ring oscillator (FREQ2) is measured and obtained. In step 1210, the obtained frequencies, FREQ1 and FREQ2, are calculated and a calculated result is converted to N/P beta ratio either based on simulated data or empirical data.

The above illustration provides many different embodiments or embodiments for implementing different features of the invention. Specific embodiments of components and processes are described to help clarify the invention. These are, of course, merely embodiments and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

What is claimed is:

1. A ring oscillator comprising a plurality of inverting modules serially and directly connected with each other with an output of a last stage inverting module coupled to an input of a first stage inverting module, each of the plurality of inverting modules always outputting a logic low voltage whenever being inputted a logic high voltage, all the forward signal paths of each of the plurality of inverting modules being formed by metal-oxide-silicon (MOS) transistors wherein all the gates of the MOS transistors being directly connected to the input of the respective inverting module, and at least one of the plurality of inverting modules having a negative feedback circuit.

2. The ring oscillator of claim 1, wherein a total number of inverting modules in the plurality of inverting modules is an odd integer.

3. The ring oscillator of claim 1, wherein each of the plurality of inverting modules comprises an inverting device with an input and an output coupled to the input and output of the inverting module, respectively, the inverting device being selected from the group consisting of an inverter, a NAND gate and a NOR gate.

4. The ring oscillator of claim 1, wherein the negative feedback circuit comprises a first PMOS transistor having a source, drain and gate coupled to a high voltage power supply (VCC), an input of the at least one inverting modules and an output of the same module, respectively.

5. The ring oscillator of claim 4 further comprising a switching device coupled between the source of the first PMOS transistor and the VCC, wherein when the switching device is turned off the feedback function of the first PMOS transistor is disabled.

6. The ring oscillator of claim 5, wherein the switching device comprises a second PMOS transistor with a source and drain coupled to the VCC and the source of the first PMOS transistor, respectively.

7. The ring oscillator of claim 1, wherein the negative feedback circuit comprises a first NMOS transistor having a source, drain and gate coupled to a ground (VSS), an input of the at least one inverting modules and an output of the same module, respectively.

8. The ring oscillator of claim 7 further comprising a switching device coupled between the source of the first NMOS transistor and the VSS, wherein when the switching device is turned off the feedback function of the first NMOS transistor is disabled.

9. The ring oscillator of claim 8, wherein the switching device comprises a second NMOS transistor with a source and drain coupled to the VSS and the source of the first NMOS transistor, respectively.

10. A ring oscillator comprising an odd number of inverting modules serially and directly connected with each other with an output of a last stage inverting module coupled to an input of a first stage inverting module, each of the odd number of inverting modules always outputting a logic low voltage whenever being inputted a logic high voltage, all the forward signal paths of each of the odd number of inverting modules being formed by metal-oxide-silicon (MOS) transistors wherein all the gates of the MOS transistors being directly connected to the input of the respective inverting module, and at least one of the odd number of inverting modules having a negative feedback circuit.

11. The ring oscillator of claim 10, wherein each of the odd number of inverting modules comprises an inverting device with an input and an output coupled to the input and output of the inverting module, respectively, the inverting device being selected from the group consisting of an inverter, a NAND gate and a NOR gate.

12. The ring oscillator of claim 10, wherein the negative feedback circuit comprises a first PMOS transistor having a source, drain and gate coupled to a high voltage power supply (VCC), an input of the at least one inverting modules and an output of the same module, respectively.

13. The ring oscillator of claim 12 further comprising a second PMOS transistor with a source and drain coupled to the VCC and the source of the first PMOS transistor, respectively, wherein when the second PMOS transistor is turned off the feedback function of the first PMOS transistor is disabled.

14. The ring oscillator of claim 10, wherein the negative feedback circuit comprises a first NMOS transistor having a source, drain and gate coupled to a ground (VSS), an input of the at least one inverting modules and an output of the same module, respectively.

15. The ring oscillator of claim 14 further comprising a second NMOS transistor with a source and drain coupled to the VSS and the source of the first NMOS, respectively, wherein when the second NMOS transistor is turned off the feedback function of the first NMOS transistor is disabled.

16. A method for extracting a CMOS transistor beta ratio, the method comprising:
providing a first CMOS ring oscillator having at least one inverting module with a first negative feedback circuit, the first ring oscillator having a unique first oscillation frequency;
providing a second CMOS ring oscillator having at least one inverting module with a second negative feedback circuit, the second ring oscillator having a unique second oscillation frequency, the second oscillation frequency being different from the first oscillation frequency;
driving the first and second ring oscillator;
obtaining the first oscillation frequency of the first ring oscillator and the second oscillation frequency of the second ring oscillator; and
converting the first and second oscillation frequencies into a CMOS transistor beta ratio.

17. The method of claim 16, wherein the driving of the first ring oscillator is followed by the driving of the second ring oscillator.

18. The method of claim 17, wherein the obtaining of the first oscillation frequency is followed by the obtaining of the second oscillation frequency.

19. The method of claim 16, wherein the converting comprises dividing the first oscillation frequency by the second oscillation frequency and extracting the CMOS beta ratio based on the division result and a set of simulation data.

20. The method of claim 16, wherein the converting comprises dividing the first oscillation frequency by the second oscillation frequency and extracting the CMOS beta ratio based on the division result and a set of empirical data.
